(19) United States
(12) Patent Application Publication
(10) Pub. No.: US 2024/0321992 A1
(43) Pub. Date: Sep. 26, 2024

(54) INTEGRATED CIRCUIT DEVICE

(71) Applicant: Samsung Electronics Co., Ltd., Suwon-si (KR)

(72) Inventors: Seungpyo HONG, Suwon-si (KR); Beomjin PARK, Suwon-si (KR); Junggil YANG, Suwon-si (KR)

(73) Assignee: Samsung Electronics Co., Ltd., Suwon-si (KR)

(21) Appl. No.: 18/531,071

(22) Filed: Dec. 6, 2023

(30) Foreign Application Priority Data
Mar. 24, 2023 (KR) 10-2023-0039009
May 8, 2023 (KR) 10-2023-0059420

(51) Int. Cl. H01L 29/423; H01L 29/06; H01L 29/08; H01L 29/66; H01L 29/775

(52) U.S. Cl. CPC H01L 29/42392; H01L 29/0673; H01L 29/0847; H01L 29/66439; H01L 29/66545; H01L 29/66553; H01L 29/775; H01L 2029/42388

(57) ABSTRACT

An integrated circuit device includes fin-type active regions extending in a first lateral direction on a substrate, a device isolation film covering sidewalls of the fin-type active regions, a gate line on the fin-type active regions and the device isolation film, nanosheet stacks on a fin top surface of each of the fin-type active regions, each nanosheet stack including at least one nanosheet and being surrounded by the gate line, a gate cut insulating portion on the device isolation film and facing an end sidewall of the gate line in a second lateral direction, and a corner insulating spacer between a first nanosheet stack of the nanosheet stacks and the gate cut insulating portion and between the device isolation film and the gate line, the first nanosheet stack being closest to the gate cut insulating portion in the second lateral direction.

### CROSS-REFERENCE TO RELATED APPLICATION

This application is based on and claims priority under 35 U.S.C. § 119 to Korean Patent Applications Nos. 10-2023-0039009 and 10-2023-0059420, respectively filed on Mar. 24, 2023 and May 8, 2023, in the Korean Intellectual Property Office, the disclosures of which are incorporated by reference herein in their entireties.

### BACKGROUND

The inventive concepts relate to integrated circuit (IC) devices, and more particularly, to IC devices including an active region of a nanowire or nanosheet type and a field-effect transistor (FET) having a gate-all-around structure including a gate surrounding the active region.

As the downscaling of IC devices has rapidly progressed, the IC devices need to ensure not only a high operating speed but also high operating accuracy. Accordingly, various studies are being conducted on IC devices configured to provide optimum or improved performance and improved reliability.

### SUMMARY

The inventive concepts provide integrated circuit (IC) devices, which include a device region having a reduced area with a downscaling trend and has a structure capable of preventing or reducing an undesired parasitic capacitance and/or a short circuit from occurring between adjacent conductive regions and improving reliability even when aspect ratios of components included in the device region increase.

According to some aspects of the inventive concepts, there is provided an IC device including a plurality of fin-type active regions extending long in a first lateral direction on a substrate, the plurality of fin-type active regions being apart from each other in a second lateral direction, wherein the second lateral direction intersects with the first lateral direction, a device isolation film covering sidewalls of each of the plurality of fin-type active regions, a gate line extending long in the second lateral direction on the plurality of fin-type active regions and the device isolation film, a plurality of nanosheet stacks on a fin top surface of each of the plurality of fin-type active regions, each nanosheet stack including at least one nanosheet, and each nanosheet stack being surrounded by the gate line, a gate cut insulating portion on the device isolation film, the gate cut insulating portion facing an end sidewall of the gate line in the second lateral direction, and a corner insulating spacer between a first nanosheet stack and the gate cut insulating portion and between the device isolation film and the gate line, the first nanosheet stack being selected from the plurality of nanosheet stacks and being closest to the gate cut insulating portion in the second lateral direction.

According to some aspects of the inventive concepts, there is provided an IC device including a fin-type active region extending long in a first lateral direction on a substrate, a device isolation film covering sidewalls of the fin-type active region, a plurality of nanosheets on a fin top surface of the fin-type active region, the plurality of nanosheets overlapping each other in a vertical direction, a gate line extending long in a second lateral direction on the fin-type active region and the device isolation film, the gate line surrounding the plurality of nanosheets, wherein the second lateral direction intersects with the first lateral direction, a source/drain region on the fin-type active region, the source/drain region being in contact with the plurality of nanosheets, a gate cut insulating portion on the device isolation film, the gate cut insulating portion facing an end sidewall of the gate line in the second lateral direction, a corner insulating spacer between the plurality of nanosheets and the gate cut insulating portion and between the device isolation film and the gate line, and a plurality of inner insulating spacers respectively one-by-one between the plurality of nanosheets, each inner insulating spacer being between the source/drain region and the gate line in the first lateral direction, wherein at least some of the plurality of inner insulating spacers include the same material as a constituent material of the corner insulating spacer.

According to some aspects of the inventive concepts, there is provided an IC device including a plurality of fin-type active regions extending long in a first lateral direction on a substrate, a device isolation film covering sidewalls of each of the plurality of fin-type active regions, a plurality of nanosheet stacks on a fin top surface of each of the plurality of fin-type active regions, each nanosheet stack including a plurality of nanosheets, a gate line extending long in a second lateral direction on the plurality of fin-type active regions and the device isolation film, the gate line surrounding a first nanosheet stack, which is selected from the plurality of nanosheet stacks, wherein the second lateral direction intersects with the first lateral direction, a source/drain region on the plurality of fin-type active regions, the source/drain region being in contact with the first nanosheet stack, a gate cut insulating portion adjacent to the first nanosheet stack on the device isolation film, the gate cut insulating portion facing an end sidewall of the gate line in the second lateral direction, a corner insulating spacer between the first nanosheet stack and the gate cut insulating portion and between the device isolation film and the gate line, and a plurality of inner insulating spacers respectively one-by-one between the plurality of nanosheets included in the first nanosheet stack, each inner insulating spacer being in contact with the source/drain region, wherein each of the corner insulating spacer and the plurality of inner insulating spacers includes silicon nitride, silicon oxide, SiOC, SiOCN, SiCN, SiBN, SiON, SiBCN, SiOF, SiOCH, or a combination thereof, and at least some of the plurality of inner insulating spacers include the same material as a constituent material of the corner insulating spacer.

### BRIEF DESCRIPTION OF THE DRAWINGS

Example embodiments of the inventive concepts will be more clearly understood from the following detailed description taken in conjunction with the accompanying drawings in which:

FIG. 1 is a plan layout diagram of some components of an integrated circuit (IC) device according to some example embodiments;

FIG. 2A is a cross-sectional view of some components in a cross-section taken along line X1-X1′ of FIG. 1;

FIG. 2B is a cross-sectional view of some components in a cross-section taken along line Y1-Y1′ of FIG. 1;

FIG. 2C is an enlarged cross-sectional view of local area “EX1” of FIG. 2B;

FIG. 3 is a cross-sectional view of an IC device according to some example embodiments;

FIG. 4 is a cross-sectional view of an IC device according to some example embodiments;

FIG. 5 is a cross-sectional view of an IC device according to some example embodiments;

FIG. 6 is a cross-sectional view of an IC device according to some example embodiments;

FIG. 7 is a cross-sectional view of an IC device according to some example embodiments; and

FIGS. 8A to 17B are cross-sectional views of a process sequence of a method of manufacturing an IC device, according to some example embodiments, wherein FIGS. 8A, 9A, 10, 11, 13A, 14A, 15A, 16A, and 17A are cross-sectional views of some components in a portion corresponding to a cross-section taken along line X1-X1′ of FIG. 1, according to a process sequence, and FIGS. 8B, 9B, 12, 13B, 14B, 15B, 16B, and 17B are cross-sectional views of some components in a portion corresponding to a cross-section taken along line Y1-Y1′ of FIG. 1, according to a process sequence.

### DETAILED DESCRIPTION

Hereinafter, example embodiments will be described in detail with reference to the accompanying drawings. The same reference numerals are used to denote the same elements in the drawings, and repeated descriptions thereof are omitted.

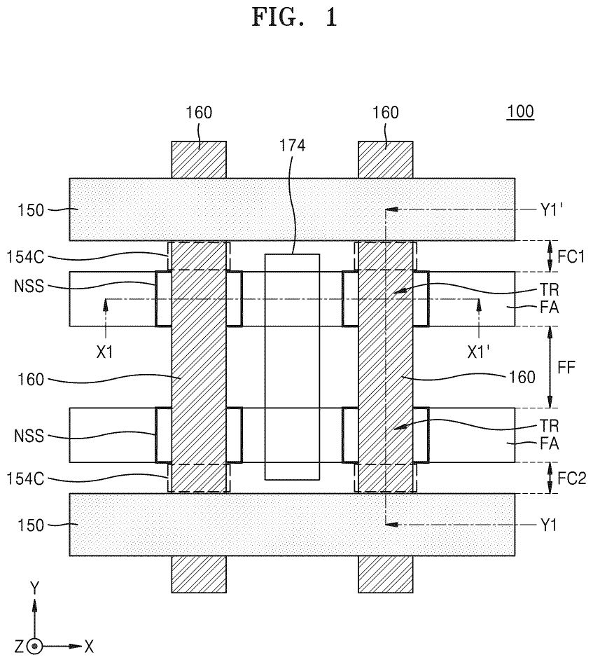

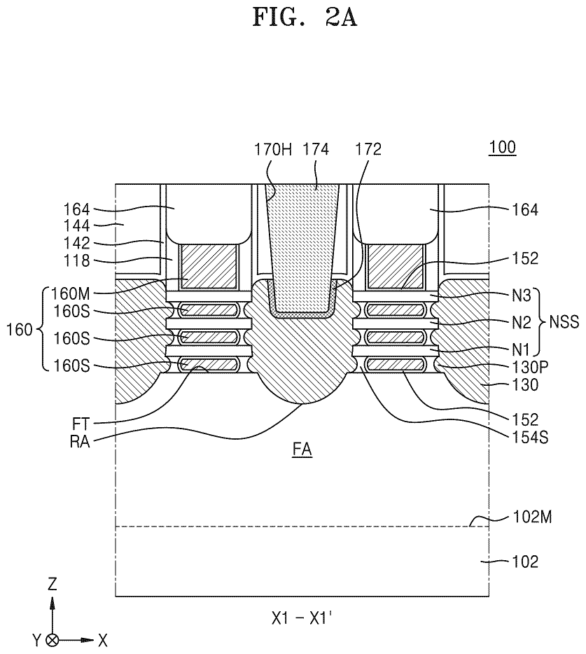

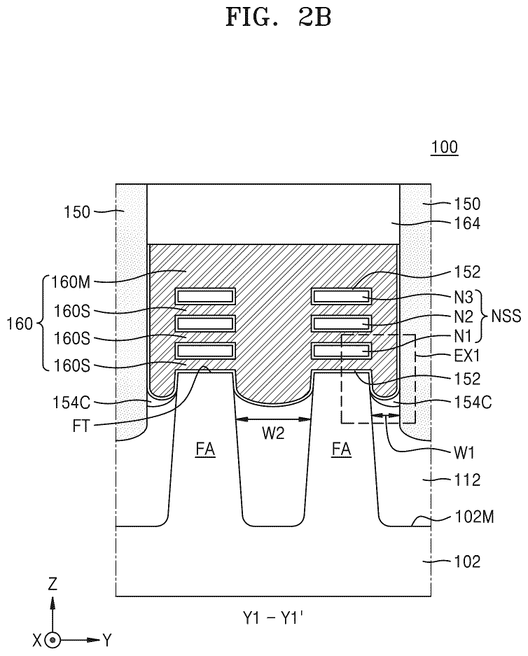

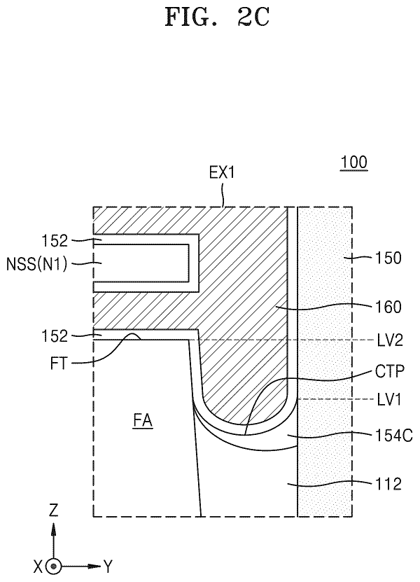

FIG. 1 is a plan layout diagram of some components of an integrated circuit (IC) device 100 according to some example embodiments. FIG. 2A is a cross-sectional view of some components in a cross-section taken along line X1-X1′ of FIG. 1. FIG. 2B is a cross-sectional view of some components in a cross-section taken along line Y1-Y1′ of FIG. 1. FIG. 2C is an enlarged cross-sectional view of local area “EX1” of FIG. 2B. The IC device 100 including a field-effect transistor (FET) having a gate-all-around structure including an active region of a nanowire or nanosheet type and a gate surrounding the active region is described with reference to FIGS. 1 and 2A to 2C.

Referring to FIGS. 1 and 2A to 2C, the IC device 100 may include a substrate 102 and a plurality of fin-type active regions FA, which protrude from the substrate 102 in a vertical direction (Z direction). The plurality of fin-type active regions FA may extend parallel to each other in a first lateral direction (X direction) and be apart from each other in a second lateral direction (Y direction), which intersects with the first lateral direction (X direction).

The substrate 102 may include a semiconductor element, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms SiGe, SiC, GaAs, InAs, InGaAs, and InP refers to a material including elements included therein, without referring to a chemical formula representing a stoichiometric relationship. The substrate 102 may include a conductive region, for example, a doped well or a doped structure.

A device isolation film 112 facing both sidewalls of each of the plurality of fin-type active regions FA may be on the substrate 102. The device isolation film 112 may include an oxide film, a nitride film, or a combination thereof.

On the plurality of fin-type active regions FA, a plurality of gate lines 160 may extend long in the second lateral direction (Y direction), which intersects with the first lateral direction (X direction). A plurality of nanosheet stacks NSS may be on respective fin top surfaces FT of the plurality of fin-type active regions FA in regions where the plurality of fin-type active regions FA intersect with the plurality of gate lines 160. The plurality of nanosheet stacks NSS may be apart from the plurality of fin-type active regions FA in the vertical direction (Z direction) and face the fin top surface FT of each of the plurality of fin-type active regions FA. As used herein, the term “nanosheet” refers to a conductive structure having a cross-section that is perpendicular or substantially perpendicular to a direction in which current flows. The nanosheet may be interpreted as including a nanowire.

Each of the plurality of nanosheet stacks NSS may include a first nanosheet N1, a second nanosheet N2, and a third nanosheet N3, which overlap each other in the vertical direction (Z direction) on the fin top surface FT of the fin-type active region FA. The first to third nanosheets N1, N2, and N3 may be at different vertical distances (Z-directional distances) from the fin top surface FT of the fin-type active region FA. The number of nanosheet stacks NSS and the number of gate lines 160 on the fin top surface FT of the fin-type active region FA are not specifically limited. For example, at least one nanosheet stack NSS and at least one gate line 160 may be on one fin-type active region FA.

Each of the plurality of nanosheet stacks NSS is illustrated as including three nanosheets (for example, the first to third nanosheets N1, N2, and N3) in FIGS. 2A and 2B, but the inventive concepts are not limited thereto. The number of nanosheets included in one nanosheet stack NSS is not specifically limited. For example, each of the plurality of nanosheet stacks NSS may include one, two, or four or more nanosheets. Each of the first nanosheet N1, the second nanosheet N2, and the third nanosheet N3 may have a channel region. In some example embodiments, the first to third nanosheets N1, N2, and N3 may have substantially the same or the same thicknesses as each other in the vertical direction (Z direction). In some embodiments, at least some of the first to third nanosheets N1, N2, and N3 may have different thicknesses from each other in the vertical direction (Z direction).

In some example embodiments, the first to third nanosheets N1, N2, and N3 in one nanosheet stack NSS may have the same or substantially the same sizes as each other in the first lateral direction (X direction). In some embodiments, at least some of the first to third nanosheets N1, N2, and N3 in one nanosheet stack NSS may have different sizes from each other in the first lateral direction (X direction). For example, in the first lateral direction (X direction), each of the first and second nanosheets N1 and N2, which are relatively close to the fin top surface FT, from among the first to third nanosheets N1, N2, and N3, may have a greater length than the third nanosheet N3, which is farthest from the fin top surface FT.

A plurality of recesses RA may be formed in a top surface of each of the plurality of fin-type active regions FA. FIG. 2A illustrates an example in which the lowermost surface of each of the plurality of recesses RA is at a lower level than the fin top surface FT of each of the plurality of fin-type active regions FA, but the inventive concepts are not limited thereto. The lowermost surface of each of the plurality of recesses RA may be at the substantially same or the same level as the fin top surface FT of the fin-type active region FA. A plurality of source/drain regions 130 may be formed on the plurality of recesses RA.

The plurality of gate lines 160 may surround each of the first to third nanosheets N1, N2, and N3 included in each of the plurality of nanosheet stacks NSS while covering the plurality of nanosheet stacks NSS on the plurality of fin-type active regions FA. A plurality of transistors TR may be respectively formed at intersections between the plurality of fin-type active regions FA and the plurality of gate lines 160 on the substrate 102. In some example embodiments, at least some of the plurality of transistors TR may be an NMOS transistor region. In some embodiments, at least some of the plurality of transistors TR may be a PMOS transistor region.

As shown in FIGS. 2A and 2B, each of the plurality of gate lines 160 may include a main gate portion 160M and a plurality of sub-gate portions 160S. The main gate portion 160M may cover the top surface of the nanosheet stack NSS and extend long in the second lateral direction (Y direction). The plurality of sub-gate portions 160S may be integrally connected to the main gate portion 160M and respectively one-by-one arranged between the first to third nanosheets N1, N2, and N3 and between the fin top surface FT of the fin-type active region FA and the first nanosheet N1.

Each of the plurality of gate lines 160 may include a metal, a metal nitride, a metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum (TaN). The metal carbide may be titanium aluminum carbide (TiAlC). In some example embodiments, each of the plurality of gate lines 160 may have a structure in which a metal nitride film, a metal film, a conductive capping film, and a gap-fill metal film are sequentially stacked. The metal nitride film and the metal film may include at least one metal selected from titanium (Ti), tantalum (Ta), tungsten (W), ruthenium (Ru), niobium (Nb), molybdenum (Mo), and hafnium (Hf). The gap-fill metal film may include tungsten (W), aluminum (Al), or a combination thereof. Each of the plurality of gate lines 160 may include at least one work-function metal-containing film. The at least one work-function metal-containing film may include at least one metal selected from Ti, W, Ru, Nb, Mo, Hf, Ni, Co, Pt, Yb, Tb, Dy, Er, and Pd. In some example embodiments, each of the plurality of gate lines 160 may have a stack structure of at least two layers selected from a first work-function metal-containing film, a second work-function metal-containing film, and a gap-fill metal film. For example, the first work-function metal-containing film may include a titanium nitride (TiN) film. The second work-function metal-containing film may include a combination of a first TiN film, a titanium aluminum carbide (TiAIC) film, and a second TiN film. In some example embodiments, each of the plurality of gate lines 160 may include a TiN film, a stack structure of TiAIC/TiN/W, a stack structure of TiN/TaN/TiAIC/TiN/W, or a stack structure of TiN/TaN/TIN/TiAIC/TiN/W. However, a constituent material of each of the plurality of gate lines 160 is not limited to the examples described above and may be variously modified and changed within the scope of the inventive concepts.

As shown in FIG. 1, the plurality of gate lines 160 may include a pair of gate lines 160, which are collinear with each other in the second lateral direction (Y direction) and apart from each other in the second lateral direction (Y direction). On the plurality of fin-type active regions FA and the device isolation film (refer to 112 in FIG. 2B), the pair of gate lines 160 may intersect with the plurality of fin-type active regions FA and extend long in the second lateral direction (Y direction).

As shown in FIGS. 1 and 2B, a gate cut insulating portion 150 may be between two adjacent ones of the plurality of gate lines 160, which are collinear with each other in the second lateral direction (Y direction). The gate cut insulating portion 150 may extend long in the first lateral direction (X direction) parallel to the plurality of fin-type active regions FA. In some example embodiments, the gate cut insulating portion 150 may include a silicon nitride film, a silicon oxide film, a silicon carbonitride (SiCN) film, a silicon oxynitride (SiON) film, a silicon oxycarbonitride (SiOCN) film, or a combination thereof, without being limited thereto.

As shown in FIGS. 2A to 2C, a gate dielectric film 152 may be between the first to third nanosheets N1, N2, and N3 of each of the plurality of nanosheet stacks NSS and the gate line 160. The gate dielectric film 152 may include portions covering respective surfaces of the first nanosheet N1, the second nanosheet N2, and the third nanosheet N3, portions covering sidewalls of the main gate portion 160M, and a portion between the gate line 160 and the gate cut insulating portion 150.

The gate cut insulating portion 150 may be on the device isolation film 112 and face an end sidewall of the gate line 160 in the second lateral direction (Y direction). The gate cut insulating portion 150 may be in contact with the gate dielectric film 152 on the end sidewall of the gate line 160 in the second lateral direction (Y direction).

In some example embodiments, the gate dielectric film 152 may include a stack structure of an interfacial film and a high-k dielectric film. The interfacial film may include a low-k dielectric material film having a dielectric constant of about or exactly 9 or less, for example, a silicon oxide film, a silicon oxynitride film, or a combination thereof. In some example embodiments, the interfacial film may be omitted. The high-k dielectric film may include a material having a higher dielectric constant than a silicon oxide film. For example, the high-k dielectric film may have a dielectric constant of about or exactly 10 to about or exactly 25. The high-k dielectric film may include hafnium oxide, without being limited thereto.

In each of the plurality of nanosheet stacks NSS, the first to third nanosheets N1, N2, and N3 may include a semiconductor layer including the same elements as each other. In some example embodiments, each of the first nanosheet N1, the second nanosheet N2, and the third nanosheet N3 may include a silicon (Si) layer.

Each of the plurality of nanosheet stacks NSS may be in contact with the source/drain region 130 adjacent thereto in the first lateral direction (X direction). In some example embodiments, the first to third nanosheets N1, N2, and N3 may be doped with a dopant of the same conductivity type as that of the source/drain region 130 that is in contact with the first to third nanosheets N1, N2, and N3. In an example, the first to third nanosheets N1, N2, and N3 may include a Si layer doped with an n-type dopant. In another example, the first to third nanosheets N1, N2, and N3 may include a Si layer doped with a p-type dopant.

As shown in FIG. 2B, the device isolation film 112 may include a portion between the fin-type active region FA and the gate cut insulating portion 150 and a portion between a pair of fin-type active regions FA.

As shown in FIG. 2A, both sidewalls of the plurality of gate lines 160 may be respectively covered by a plurality of outer insulating spacers 118 in the first lateral direction (X direction). Each of the plurality of outer insulating spacers 118 may include a portion covering both sidewalls of the main gate portion 160M on the top surface of the nanosheet stack NSS and a portion covering the gate line 160 on the device isolation film 112. Each of the plurality of outer insulating spacers 118 may be apart from the gate line 160 with the gate dielectric film 152 therebetween.

In some example embodiments, each of the plurality of outer insulating spacers 118 may include silicon nitride, silicon oxide, silicon oxycarbide (SiOC), silicon oxycarbonitride (SiOCN), silicon carbonitride (SiCN), silicon boron nitride (SiBN), silicon oxynitride (SiON), silicon boron carbonitride (SiBCN), fluorinated silicon oxide (SiOF), hydrogenated silicon oxycarbide (SiOCH), or a combination thereof. The plurality of outer insulating spacers 118 may include a single film including a selected one of the materials described above or a multilayered film including a plurality of material films selected from the materials described above. As used herein, each of the terms SiOC, SiOCN, SiCN, SiBN, SiON, SiBCN, SiOF, and SiOCH refers to a material including elements included therein, without referring to a chemical formula representing a stoichiometric relationship.

As shown in FIG. 2A, a plurality of inner insulating spacers 154S may be between the first to third nanosheets N1, N2, and N3 and between the fin top surface FT of the fin-type active region FA and the first nanosheet N1.

In the first lateral direction (X direction), both sidewalls of each of the plurality of sub-gate portions 160S may be covered by the inner insulating spacers 154S with the gate dielectric film 152 therebetween. Each of the plurality of sub-gate portions 160S may be apart from the source/drain region 130 with the gate dielectric film 152 and the inner insulating spacer 154S therebetween. At least some of the plurality of inner insulating spacers 154S may overlap the outer insulating spacer 118 in the vertical direction (Z direction). As used herein, it will be understood that when a first component is referred to as overlapping a second component in the vertical direction (Z direction), one straight line in the vertical direction (Z direction) may extend to pass the first component and the second component.

Each of the plurality of source/drain regions 130 may be in contact with the plurality of inner insulating spacers 154S adjacent thereto in the first lateral direction (X direction). Each of the plurality of inner insulating spacers 154S may include a sidewall facing the sub-gate portion 160S of the gate line 160 and a sidewall facing the source/drain region 130 adjacent thereto. As used herein, from among the sidewalls of each of the plurality of inner insulating spacers 154S, the sidewall facing the sub-gate portion 160S of the gate line 160 may be referred to as a first sidewall and the sidewall facing the source/drain region 130 adjacent thereto may be referred to as a second sidewall. In some example embodiments, the first sidewall and the second sidewall may be asymmetrical with each other about one line passing through the inner insulating spacer 154S in the vertical direction (Z direction). In some embodiments, the first sidewall and the second sidewall may be symmetrical with each other about one line passing through the inner insulating spacer 154S in the vertical direction (Z direction).

Each of the plurality of inner insulating spacers 154S may include silicon nitride, silicon oxide, SiOC, SiOCN, SiCN, SiBN, SiON, SiBCN, SIOF, SiOCH, or a combination thereof. The plurality of inner insulating spacers 154S may include a single film including a selected one of the materials described above or a multilayered film including a plurality of material films selected from the materials described above.

Each of the plurality of source/drain regions 130 may include portions in contact with the plurality of inner insulating spacers 154S adjacent thereto. Each of the plurality of source/drain regions 130 may include a protrusion 130P, which protrudes toward the sub-gate portion 160S of the gate line 160. In each of the plurality of source/drain regions 130, the protrusion 130P may overlap at least one of the first to third nanosheets N1, N2, and N3 included in the nanosheet stack NSS in the vertical direction (Z direction).

In some example embodiments, the outer insulating spacer 118 and the inner insulating spacer 154S may include the same materials as each other. In some embodiments, the outer insulating spacer 118 and the inner insulating spacer 154S may include different materials from each other.

As shown in FIG. 2A, between the first to third nanosheets N1, N2, and N3 and between the fin-type active region FA and the first nanosheet N1, both sidewalls of each of the plurality of sub-gate portions 160S may be apart from the source/drain region 130 with the gate dielectric film 152 and the inner insulating spacer 154S therebetween in the first lateral direction (X direction). Each of the plurality of source/drain regions 130 may face the nanosheet stack NSS and the plurality of sub-gate portions 160S in the first lateral direction (X direction). The gate dielectric film 152 may include a portion in contact with the source/drain region 130.

As shown in FIG. 2A, the main gate portion 160M of the gate line 160 may be apart from the source/drain region 130 with the outer insulating spacer 118 therebetween.

In some example embodiments, at least some of the plurality of source/drain regions 130 may include a Si layer doped with an n-type dopant or a SiC layer doped with an n-type dopant. The n-type dopant may be selected from phosphorus (P), arsenic (As), and antimony (Sb). In some embodiments, at least some of the plurality of source/drain regions 130 may include a SiGe layer doped with a p-type dopant. The p-type dopant may be selected from boron (B) and gallium (Ga). Shapes of the plurality of source/drain regions 130 are not limited to those shown in FIG. 2A. Each of the plurality of source/drain regions 130 may have various shapes and sizes according to a channel type of the transistor TR.

As shown in FIGS. 1, 2B, and 2C, when a nanosheet stack NSS closest to the gate cut insulating portion 150, from among the plurality of nanosheet stacks NSS surrounded by one gate line 160, is referred to as a first nanosheet stack NSS, a corner insulating spacer 154C may be between the first nanosheet stack NSS and the gate cut insulating portion 150 and between the device isolation film 112 and the gate line 160.

The corner insulating spacer 154C may be in contact with each of the gate cut insulating portion 150 and the device isolation film 112. The corner insulating spacer 154C may be apart from the gate line 160 with the gate dielectric film 152 therebetween.

As shown in FIGS. 1 and 2B, in the second lateral direction (Y direction), a distance FC1 or FC2 between the first nanosheet stack NSS and the gate cut insulating portion 150 may be less than a distance between two adjacent ones of the plurality of nanosheet stacks NSS. In the second lateral direction (Y direction), a width W1 of a portion of the device isolation film 112, which is between the fin-type active region FA and the gate cut insulating portion 150, may be less than a width W2 of a portion of the device isolation film 112, which is between a pair of fin-type active regions FA.

As shown in FIGS. 2B and 2C, a first vertical level LV1 of an uppermost portion of the corner insulating spacer 154C, which is farthest from the main surface 102M of the substrate 102, may be closer to the main surface 102M of the substrate 102 than a second vertical level LV2 of the fin top surface FT of the fin-type active region FA. As used herein, the term “vertical level” refers to a distance from the main surface 102M of the substrate 102 in the vertical direction (Z direction or −Z direction).

The gate dielectric film 152 may include a portion between the gate line 160 and the corner insulating spacer 154C. A top surface CTP of the corner insulating spacer 154C, which faces the gate line 160, may have a concave shape toward the gate line 160. The corner insulating spacer 154C may include a portion of which a thickness in the vertical direction (Z direction) gradually increases toward the gate cut insulating portion 150 in the second lateral direction (Y direction).

The gate line 160 may include a portion (hereinafter, referred to as a first gate portion) between the nanosheet stack NSS and the gate cut insulating portion 150 and a portion (hereinafter, referred to as a second gate portion) between two adjacent nanosheet stacks NSS. As shown in FIG. 2B, in the gate line 160, a thickness of the first gate portion in the vertical direction (Z direction) may be less than a thickness of the second gate portion in the vertical direction (Z direction). In the gate line 160, a vertical distance between a lowermost surface of the first gate portion, which faces the substrate 102, and the main surface 102M of the substrate 102 may be greater than a vertical distance between a lowermost surface of the second gate portion, which faces the substrate 102, and the main surface 102M of the substrate 102. As used herein, the term “vertical distance” refers to a size in the vertical direction (Z direction).

The corner insulating spacer 154C may include silicon nitride, silicon oxide, SiOC, SiOCN, SiCN, SiBN, SiON, SiBCN, SiOF, SiOCH, or a combination thereof. In some example embodiments, the corner insulating spacer 154C may include a single film including a selected one of the materials described above. In some example embodiments, at least some of the plurality of inner insulating spacers 154S may include the same materials as a constituent material of the corner insulating spacer 154C.

As shown in FIGS. 2A and 2B, a top surface of each of the gate line 160 and the gate dielectric film 152 may be covered by a capping insulating layer 164. The capping insulating layer 164 may include a silicon nitride film or a SiCN film, without being limited thereto.

As shown in FIG. 2A, the plurality of source/drain regions 130 may be covered by an insulating liner 142. The insulating liner 142 may conformally cover a surface of each of the plurality of source/drain regions 130 and the outer insulating spacer 118. As shown in FIGS. 2A and 2B, a top surface of the capping insulating layer 164, a top surface of the gate cut insulating portion 150, a top surface of the insulating liner 142, and a top surface of an inter-gate dielectric film 144 may be coplanar with each other. The insulating liner 142 may include a silicon nitride film, a SiCN film, a SiBN film, a SiON film, a SiOCN film, a SiBCN film, a SiOC film, a silicon oxide film, or a combination thereof, without being limited thereto. The insulating liner 142 may be covered by the inter-gate dielectric film 144. The inter-gate dielectric film 144 may include a silicon oxide film, a silicon nitride film, a SiON film, a SiOCN film, or a combination thereof, without being limited thereto.

As shown in FIG. 2B, a bottom surface of the gate cut insulating portion 150 may be apart from the main surface 102M of the substrate 102 with the device isolation film 112 therebetween in the vertical direction (Z direction). The device isolation film 112 may surround a lower portion of the gate cut insulating portion 150.

As shown in FIGS. 1 and 2A, a metal silicide film 172 and a source/drain contact 174 may be on the source/drain region 130. The metal silicide film 172 may be in contact with the source/drain region 130. The source/drain contact 174 may fill a contact hole 170H, which passes through the inter-gate dielectric film 144 and the insulating liner 142 in the vertical direction (Z direction). The source/drain contact 174 may be in contact with the metal silicide film 172 and be connected to the source/drain region 130 through the metal silicide film 172. The source/drain contact 174 may pass through a portion of the source/drain region 130 in the vertical direction (Z direction). The insulating liner 142 and the inter-gate dielectric film 144 may surround a sidewall of the source/drain contact 174.

As shown in FIG. 1, the source/drain contact 174 may be adjacent to each of the gate cut insulating portion 150 and the gate line 160. The corner insulating spacer 154C and the source/drain contact 174 may overlap each other in the first lateral direction (X direction). As used herein, it will be understood that when a first component is referred to as overlapping a second component in the first lateral direction (X direction), one straight line in the first lateral direction (X direction) may extend to pass the first component and the second component.

In some example embodiments, the metal silicide film 172 may include Ti, W, Ru, Nb, Mo, Hf, Ni, Co, Pt, Yb, Tb, Dy, Er, or Pd. For example, the metal silicide film 172 may include titanium silicide. In some example embodiments, the source/drain contact 174 may include a conductive barrier film and a metal plug surrounded by the conductive barrier film. The conductive barrier film may include Ti, Ta, TiN, TaN, or a combination thereof, and the metal plug may include W, Co, Mo, Cu, Ru, Mn, or a combination thereof, without being limited thereto. In some embodiments, the source/drain contact 174 may not include the conductive barrier film.

The IC device 100 described with reference to FIGS. 1 and 2A to 2C may include the corner insulating spacer 154C covering a bottom surface of the gate line 160 in a narrow space between the nanosheet stack NSS configured to provide the channel region and the gate cut insulating portion 150 configured to separate a pair of gate lines 160, which are adjacent to each other and collinear with each other in the second lateral direction (Y direction). Accordingly, a length of the gate line 160 in the vertical direction (Z direction) may be prevented or reduced from unnecessarily increasing in a relatively narrow space between the gate cut insulating portion 150 and the nanosheet stack NSS. As a result, a leakage current from the gate line 160 may be inhibited from occurring and an undesired parasitic capacitance and/or a short circuit may be prevented or reduced from occurring between the gate line 160 and another conductive region (e.g., the source/drain contact 174) adjacent thereto. Therefore, a plurality of transistors TR included in the IC device 100 may provide optimum or increased performance and the operating speed and reliability of the IC device 100 may improve.

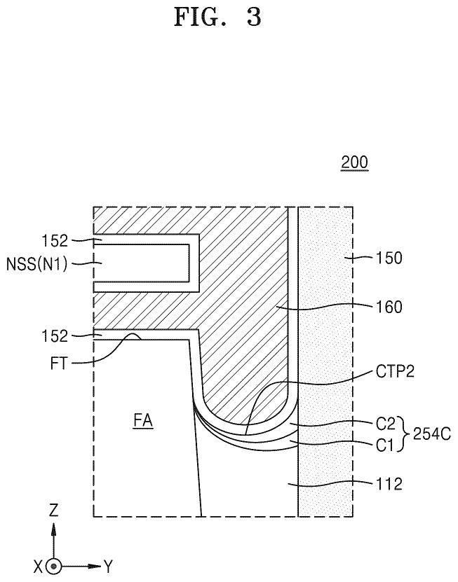

FIG. 3 is a cross-sectional view of an IC device 200 according to some example embodiments. FIG. 3 illustrates an enlarged cross-sectional configuration of a portion corresponding to local area “EX1” of FIG. 2B in the IC device 200. In FIG. 3, the same reference numerals are used to denote the same elements as in FIGS. 1 and 2A to 2C, and repeated descriptions thereof are omitted.

Referring to FIG. 3, the IC device 200 may substantially have the same configuration as the IC device 100 described with reference to FIGS. 1 and 2A to 2C. However, the IC device 200 may include a corner insulating spacer 254C having a multilayered structure.

The corner insulating spacer 254C may include a plurality of corner insulating films. The plurality of corner insulating films may include a first corner insulating film C1 and a second corner insulating film C2, which are sequentially stacked on the device isolation film 112. The first corner insulating film C1 and the second corner insulating film C2 may include different insulating materials from each other. In some example embodiments, the first corner insulating film C1 and the second corner insulating film C2 may include respectively different materials, each of which is selected from silicon nitride, silicon oxide, SiOC, SiOCN, SiCN, SiBN, SiON, SiBCN, SiOF, and SiOCH. For example, the first corner insulating film C1 may include a silicon oxide film and the second corner insulating film C2 may include a silicon nitride film, without being limited thereto.

The second corner insulating film C2, which constitutes an uppermost layer of the corner insulating spacer 254C, may have a top surface CTP2 facing the gate line 160. The top surface CTP2 of the second corner insulating film C2 may have a concave shape toward the gate line 160. The corner insulating spacer 254C may include a portion of which a thickness in a vertical direction (Z direction) gradually increases toward the gate cut insulating portion 150 in a second lateral direction (Y direction).

FIG. 3 illustrates an example in which the corner insulating spacer 254C has a double structure including the first corner insulating film C1 and the second corner insulating film C2, but the inventive concepts are not limited thereto. For example, the corner insulating spacer 254C may include at least three corner insulating films including different insulating materials from each other Details of the corner insulating spacer 254C may be substantially the same or the same as those of the corner insulating spacer 154C described with reference to FIGS. 1, 2B, and 2C.

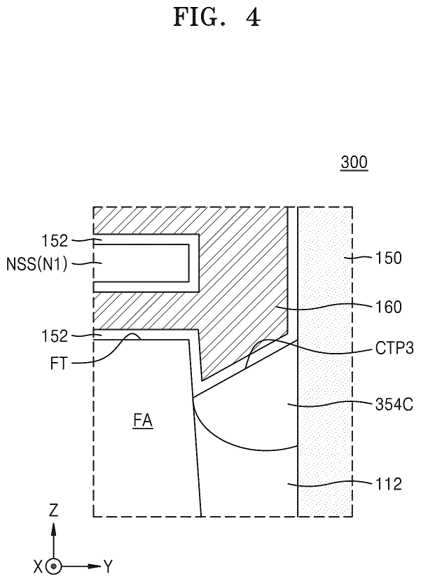

FIG. 4 is a cross-sectional view of an IC device 300 according to some example embodiments. FIG. 4 illustrates an enlarged cross-sectional configuration of a portion corresponding to local area “EX1” of FIG. 2B in the IC device 300. In FIG. 4, the same reference numerals are used to denote the same elements as in FIGS. 1 and 2A to 2C, and repeated descriptions thereof are omitted.

Referring to FIG. 4, the IC device 300 may substantially have the same configuration as the IC device 100 described with reference to FIGS. 1 and 2A to 2C. However, the IC device 300 may include a corner insulating spacer 354C.

The corner insulating spacer 354C may have a top surface CTP3 facing the gate line 160. The top surface CT3 of the corner insulating spacer 354C may include an inclined surface that extends away from the substrate 102 toward a gate cut insulating portion 150. The corner insulating spacer 354C may include a portion of which a thickness in a vertical direction (Z direction) gradually increases toward the gate cut insulating portion 150 in a second lateral direction (Y direction). Details of the corner insulating spacer 354C may be substantially the same or the same as those of the corner insulating spacer 154C described with reference to FIGS. 1, 2B, and 2C.

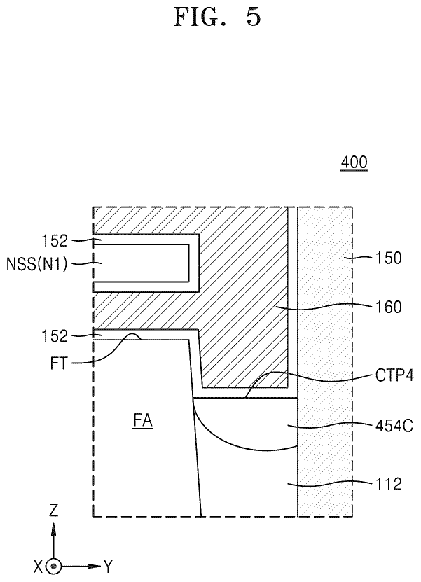

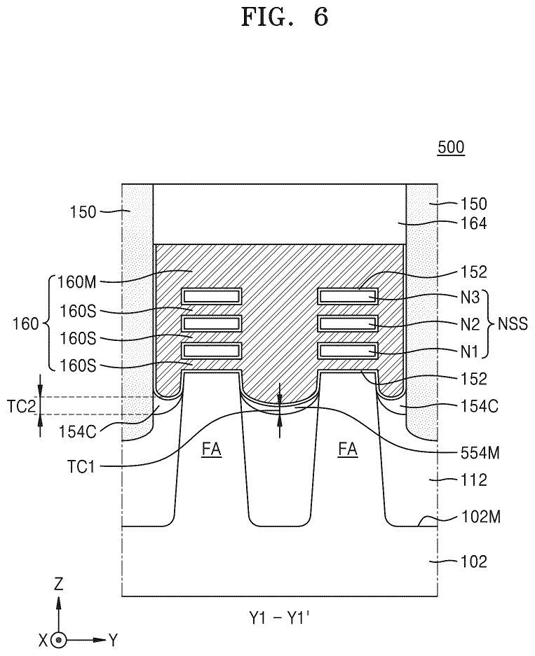

FIG. 5 is a cross-sectional view of an IC device 400 according to some example embodiments. FIG. 5 illustrates an enlarged cross-sectional configuration of a portion corresponding to local area “EX1” of FIG. 2B in the IC device 400. In FIG. 5, the same reference numerals are used to denote the same elements as in FIGS. 1 and 2A to 2C, and repeated descriptions thereof are omitted.

Referring to FIG. 5, the IC device 400 may substantially have the same configuration as the IC device 100 described with reference to FIGS. 1 and 2A to 2C. However, the IC device 400 may include a corner insulating spacer 454C.

The corner insulating spacer 454C may have a top surface CTP4 facing the gate line 160. The top surface CTP4 of the corner insulating spacer 454C may include a planar surface, which extends planar in a second lateral direction (Y direction). FIG. 5 illustrates an example in which the top surface CTP4 of the corner insulating spacer 454C is linear in the second lateral direction (Y direction), but the inventive concepts are not limited thereto. For example, the top surface CTP4 of the corner insulating spacer 454C may include a concave surface toward the gate line 160 or a convex surface toward the gate line 160. Details of the corner insulating spacer 454C may be substantially the same or the same as those of the corner insulating spacer 154C described with reference to FIGS. 1, 2B, and 2C.

FIG. 6 is a cross-sectional view of an IC device 500 according to some example embodiments. FIG. 6 illustrates some components in a portion of the IC device 500, which corresponds to a cross-section taken along line Y1-Y1′ of FIG. 1. In FIG. 6, the same reference numerals are used to denote the same elements as in FIGS. 1 and 2A to 2C, and repeated descriptions thereof are omitted.

Referring to FIG. 6, the IC device 500 may substantially have the same configuration as the IC device 100 described with reference to FIGS. 1 and 2A to 2C. However, the IC device 500 may include a middle insulating spacer 554M.

The IC device 500 may include a plurality of nanosheet stacks NSS, which are adjacent to each other in a second lateral direction (Y direction) and surrounded by one gate line 160. The middle insulating spacer 554M may be between a pair of nanosheet stacks NSS adjacent to each other, from among the plurality of nanosheet stacks NSS surrounded by one gate line 160, and between the device isolation film 112 and the gate line 160. In a vertical direction (Z direction), a greatest thickness TC1 of the middle insulating spacer 554M may be less than a greatest thickness TC2 of a corner insulating spacer 154C.

A top surface of the middle insulating spacer 554M may be in contact with the gate dielectric film 152 and face the gate line 160 with the gate dielectric film 152 therebetween. A bottom surface of the middle insulating spacer 554M may be in contact with a top surface of the device isolation film 112. A vertical level of an uppermost surface of the middle insulating spacer 554M may be closer to a main surface 102M of a substrate 102 than a vertical level of a fin top surface FT of the fin-type active region FA.

The middle insulating spacer 554M may include silicon nitride, silicon oxide, SiOC, SiOCN, SiCN, SiBN, SiON, SiBCN, SiOF, SiOCH, or a combination thereof. In some example embodiments, the middle insulating spacer 554M may include a single film including a selected one of the materials described above or a multilayered film including a plurality of material films selected from the materials described above. In some example embodiments, the middle insulating spacer 554M and the corner insulating spacer 154C may include the same materials as each other.

In the IC device 500, even when a vertical level of the top surface of the device isolation film 112 becomes relatively low, because the top surface of the device isolation film 112 is covered by the middle insulating spacer 554M and the corner insulating spacer 154C, a length of the gate line 160 in the vertical direction (Z direction) may be prevented or reduced from unnecessarily increasing. Accordingly, a parasitic capacitance caused by coupling between the gate line 160 and conductive regions adjacent thereto may be reduced. Therefore, the reliability of the IC device 500 may improve.

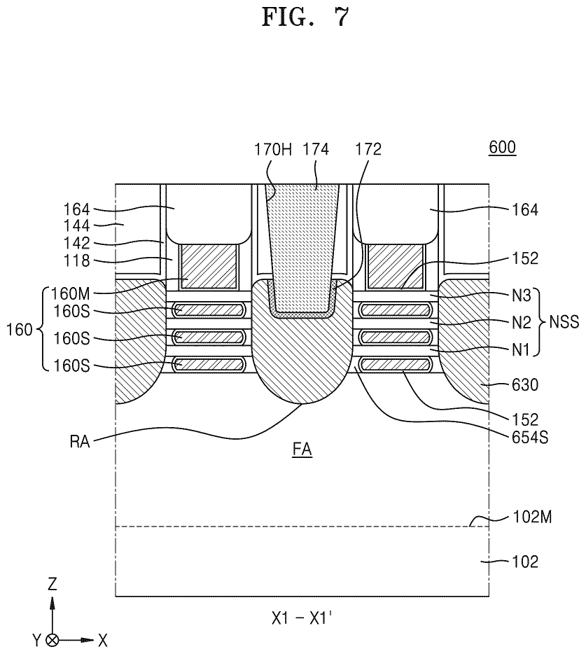

FIG. 7 is a cross-sectional view of an IC device 600 according to some example embodiments. FIG. 7 illustrates some components in a portion of the IC device 600, which corresponds to a cross-section taken along line X1-X1′ of FIG. 1. In FIG. 7, the same reference numerals are used to denote the same elements as in FIGS. 1 and 2A to 2C, and repeated descriptions thereof are omitted.

Referring to FIG. 7, the IC device 600 may substantially have the same configuration as the IC device 200 described with reference to FIGS. 1 and 2A to 2C. However, the IC device 600 may include a plurality of source/drain regions 630 and a plurality of inner insulating spacers 654S in contact with the plurality of source/drain regions 630.

Each of the plurality of source/drain regions 630 may substantially have the same configuration as the source/drain region 130 described with reference to FIG. 2A. However, unlike the source/drain region 130 described with reference to FIG. 2A, each of the plurality of source/drain regions 630 may not include a protrusion (refer to 130P in FIG. 2A), which is convex toward the sub-gate portion 160S of the gate line 160. Each of the plurality of source/drain regions 630 may not include a portion overlapping the first to third nanosheets N1, N2, and N3 included in the nanosheet stack NSS adjacent thereto in a vertical direction (Z direction).

Each of the plurality of inner insulating spacers 654S may substantially have the same configuration as the inner insulating spacer 14S described with reference to FIG. 2A. However, each of the plurality of inner insulating spacers 654S may include a first sidewall facing the sub-gate portion 160S of the gate line 160 and a second sidewall facing the source/drain region 630. The first sidewall and the second sidewall may be asymmetrical with each other about one line passing through the inner insulating spacer 654S in the vertical direction (Z direction). For example, of the inner insulating spacer 654S, the first sidewall may have a curved surface having a first radius of curvature, and the second sidewall may include a curved surface having a second radius of curvature, which is greater than the first radius of curvature, or include a planar surface without a curved surface.

Similar to the IC device 100 described with reference to FIGS. 1 and 2A to 2C, the IC devices 200, 300, 400, 500, and 600 described with reference to FIGS. 3 to 7 may include corner insulating spacers 154C, 254C, 354C, and 454C, each of which covers a bottom surface of the gate line 160 in a narrow space between the nanosheet stack NSS configured to provide a channel region and the gate cut insulating portion 150 configured to separate a pair of gate lines 160, which are adjacent to each other and collinear with each other in the second lateral direction (Y direction). Accordingly, even when the area of a device region is reduced with the downscaling of the IC devices 200, 300, 400, 500, and 600, a length of the gate line 160 in the vertical direction (Z direction) may be prevented or reduced from unnecessarily increasing in a relatively narrow space between the gate cut insulating portion 150 and the nanosheet stack NSS. As a result, a leakage current from the gate line 160 may be inhibited from occurring and an undesired parasitic capacitance and/or a short circuit may be prevented or reduced from occurring between the gate line 160 and another conductive region adjacent thereto. Therefore, a plurality of transistors included in each of the IC devices 200, 300, 400, 500, and 600 may provide optimum or increased performance and the operating speed and reliability of the IC devices 200, 300, 400, 500, and 600 may improve.

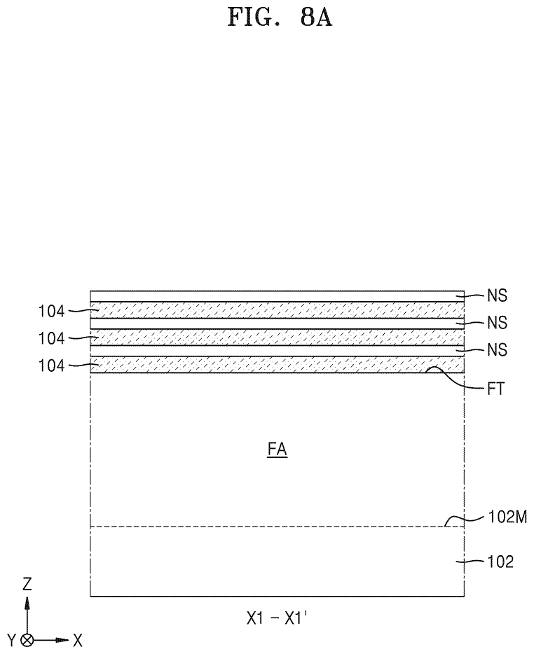

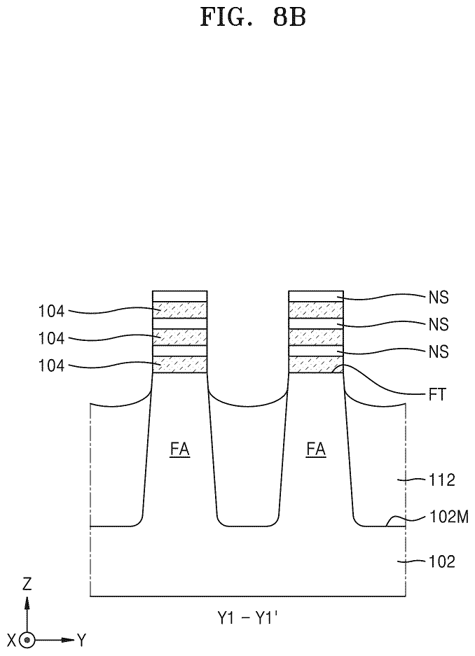

FIGS. 8A to 17B are cross-sectional views of a process sequence of a method of manufacturing an IC device, according to some example embodiments. More specifically, FIGS. 8A, 9A, 10, 11, 13A, 14A, 15A, 16A, and 17A are cross-sectional views of some components in a portion corresponding to a cross-section taken along line X1-X1′ of FIG. 1, according to a process sequence. FIGS. 8B, 9B, 12, 13B, 14B, 15B, 16B, and 17B are cross-sectional views of some components in a portion corresponding to a cross-section taken along line Y1-Y1′ of FIG. 1, according to a process sequence. An example of a method of manufacturing the IC device 100 shown in FIGS. 1 and 2A to 2C is described with reference to FIGS. 8A to 17B. In FIGS. 8A to 17B, the same reference numerals are used to denote the same elements as in FIGS. 1 and 2A to 2C, and repeated descriptions thereof are omitted.

Referring to FIGS. 8A and 8B, a stack structure in which a plurality of sacrificial semiconductor layers 104 and a plurality of nanosheet semiconductor layers NS are alternately stacked one-by-one may be formed on a substrate 102. Thereafter, the stack structure and an upper portion of the substrate 102 may be patterned to form a plurality of fin-type active regions FA. The stack structure in which the plurality of sacrificial semiconductor layers 104 and the plurality of nanosheet semiconductor layers NS are alternately stacked one-by-one may remain on each of the plurality of fin-type active regions FA.

The plurality of sacrificial semiconductor layers 104 and the plurality of nanosheet semiconductor layers NS may include semiconductor materials having different etch selectivities from each other. In some example embodiments, each of the plurality of nanosheet semiconductor layers NS may include a silicon (Si) layer and each of the plurality of sacrificial semiconductor layers 104 may include a silicon germanium (SiGe) layer. In some example embodiments, the plurality of sacrificial semiconductor layers 104 may have a constant Ge content. The SiGe layer included in the plurality of sacrificial semiconductor layers 104 may have a constant Ge content, which is selected in a range of about or exactly 5 at % to about or exactly 60 at %, for example, about or exactly 10 at % to about or exactly 40 at % (at % being atomic percentage, or a percentage of a particular type of atoms to total atoms of a material/feature). The Ge concentration of the SiGe layer included in the plurality of sacrificial semiconductor layers 104 may be variously selected as needed.

Thereafter, a device isolation film 112 may be formed to fill respective spaces between the plurality of fin-type active regions FA and cover sidewalls of each of the plurality of fin-type active regions FA. After the device isolation film 112 is formed, a top surface of an uppermost one of the plurality of nanosheet semiconductor layers NS may be exposed. A vertical level of an uppermost surface of the device isolation film 112 may be equal to or lower than a vertical level of a fin top surface FT of each of the plurality of fin-type active regions FA.

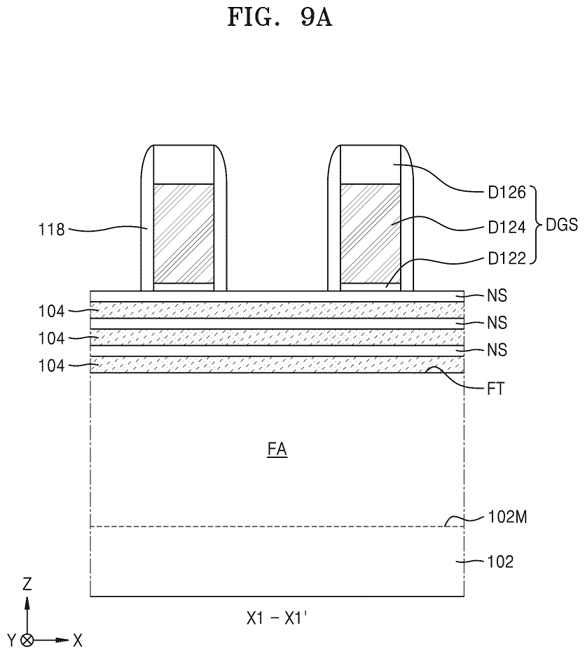

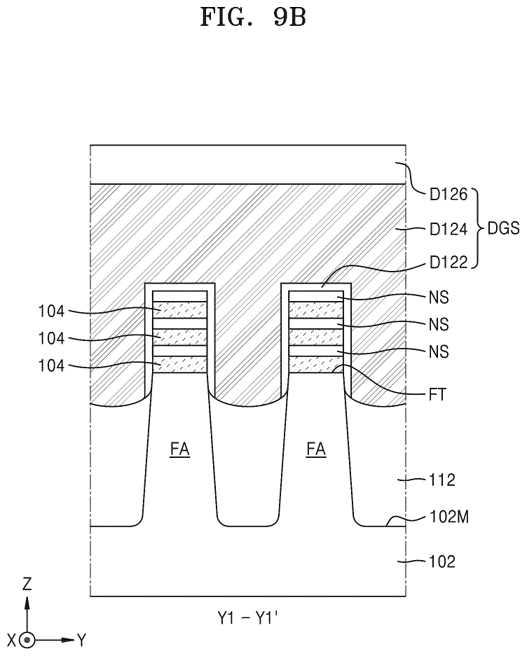

Referring to FIGS. 9A and 9B, a plurality of dummy gate structures DGS and outer insulating spacers 118 may be formed on the resultant structure of FIGS. 8A and 8B. The outer insulating spacers 118 may cover both sidewalls of each of the plurality of dummy gate structures DGS. The plurality of dummy gate structures DGS may be formed at positions corresponding to the plurality of gate lines 160 shown in FIG. 1A and continuously extend long in a second lateral direction (Y direction).

Each of the plurality of dummy gate structures DGS may have a structure in which an oxide film D122, a dummy gate layer D124, and a capping layer D126 are sequentially stacked. In some example embodiments, the dummy gate layer D124 may include a polysilicon film and the capping layer D126 may include a silicon nitride film.

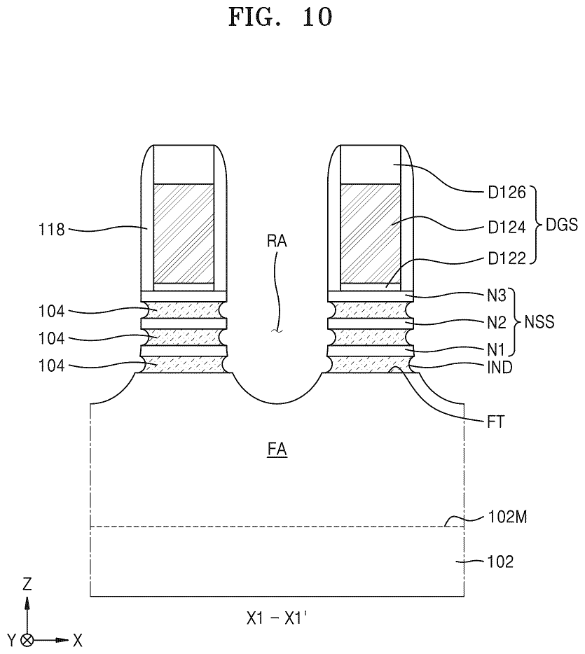

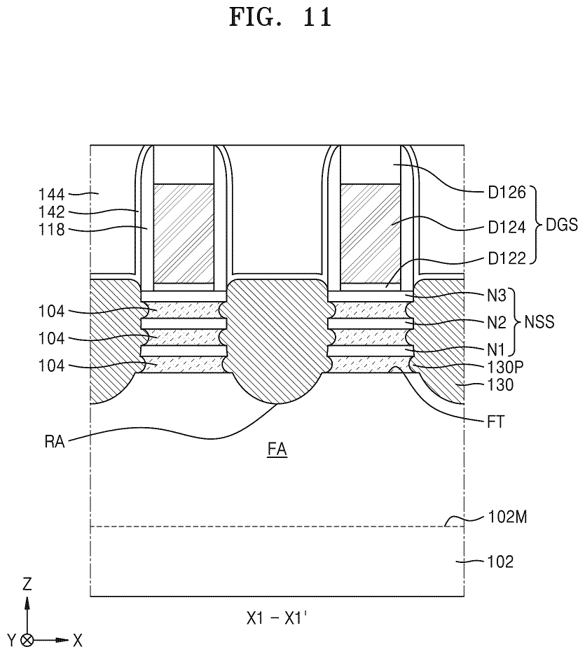

Referring to FIG. 10, in the resultant structure of FIGS. 9A and 9B, respective portions of the plurality of sacrificial semiconductor layers 104 and the plurality of nanosheet semiconductor layers NS may be removed by using the dummy gate structure DGS and the outer insulating spacers 118 as etch masks. Thus, a plurality of nanosheet stacks NSS may be formed from the plurality of nanosheet semiconductor layers NS. Each of the plurality of nanosheet stacks NSS may include first to third nanosheets N1, N2, and N3.

Thereafter, a partial region of the fin-type active region FA exposed between every two adjacent ones of the plurality of nanosheet stacks NSS may be etched, and thus, a plurality of first recesses RI may be formed in an upper portion of the fin-type active region FA. To form the plurality of recesses RA, the fin-type active region FA may be etched by using a dry process, a wet process, or a combination thereof. During the formation of the plurality of recesses RA, portions of the plurality of sacrificial semiconductor layers 104 exposed at sidewalls of the plurality of recesses RA may be etched, and thus, an indent IND may be formed at the sidewall of each of the plurality of sacrificial semiconductor layers 104. A space extending more toward the outside of the recess RA than sidewalls of the first to third nanosheets N1, N2, and N3 may be defined by the indent IND of each of the plurality of sacrificial semiconductor layers 104.

Referring to FIG. 11, a plurality of source/drain regions 130 may be formed on the fin-type active region FA on both sides of each of the plurality of nanosheet stacks NSS.

To form the plurality of source/drain regions 130, a semiconductor material may be epitaxially grown from a surface of the fin-type active region FA, which is exposed at a bottom surface of each of the plurality of recesses RA, and a sidewall of each of the first to third nanosheets N1, N2, and N3. Each of the plurality of source/drain regions 130 may be formed to include a protrusion 130P in contact with the indent IND of each of the plurality of sacrificial semiconductor layers 104.

In some example embodiments, to form the plurality of source/drain regions 130, a low-pressure chemical vapor deposition (LPCVD) process, a selective epitaxial growth (SEG) process, or a cyclic deposition and etching (CDE) process may be performed by using source materials including a semiconductor element precursor.

In some example embodiments, at least some of the plurality of source/drain regions 130 may include a Si layer doped with an n-type dopant. In this case, to form the plurality of source/drain regions 130, silane (SiH₄), disilane (Si₂H₆), trisilane (Si₃H₈), and/or dichlorosilane (SiH₂Cl₂) may be used as the Si source. The n-type dopant may be selected from phosphorus (P), arsenic (As), and antimony (Sb).

In some embodiments, at least some of the plurality of source/drain regions 130 may include a SiGe layer doped with a p-type dopant. In this case, to form the plurality of source/drain regions 130, a silicon (Si) source and a germanium (Ge) source may be used. Silane (SiH₄), disilane (Si₂H₆), trisilane (Si₃H₈), and/or dichlorosilane (SiH₂Cl₂) may be used as the Si source. Germane (GeH₄), digermane (Ge₂H₆), trigermane (Ge₃Hs), tetragermane (Ge₄H₁₀), and/or dichlorogermane (Ge₂H₂Cl₂) may be used as the Ge source. The p-type dopant may be selected from boron (B) and gallium (Ga).

An insulating liner 142 may be formed to cover respective surfaces of the source/drain regions 130, respective surfaces of a plurality of insulating spacers 118, and an exposed surface of the device isolation film 112, and an inter-gate dielectric film 144 may be formed on the insulating liner 142.

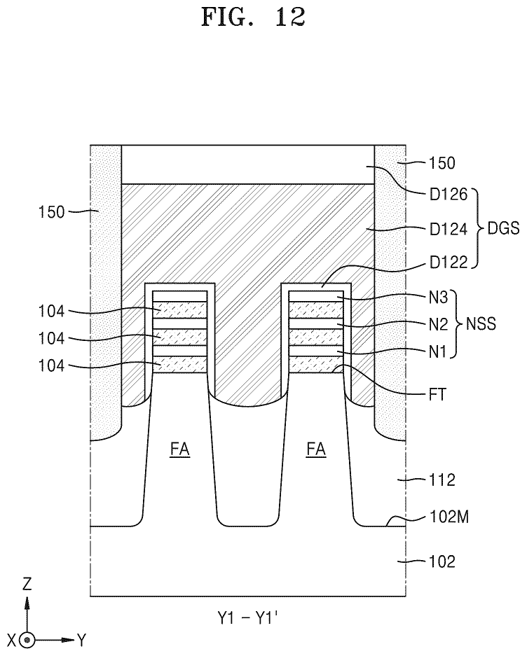

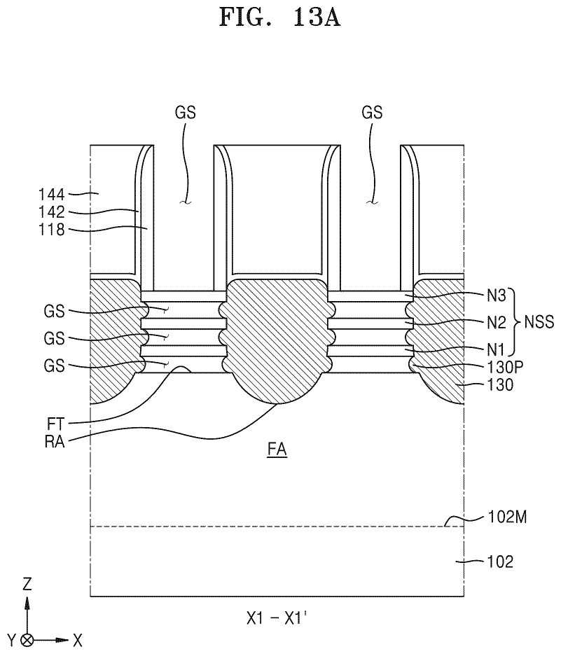

Referring to FIG. 12, a partial region of the resultant structure of FIG. 11 may be etched, and thus, a plurality of cut spaces to be filled by a plurality of gate cut insulating portions 150 may be prepared. To form the plurality of cut spaces, a portion of each of the plurality of dummy gate structures DGS, a portion of the device isolation film 112, a portion of the inter-gate dielectric film 144, and a portion of the insulating liner 142 may be etched. Thereafter, the plurality of cut spaces may be filled by the plurality of gate cut insulating portions 150.

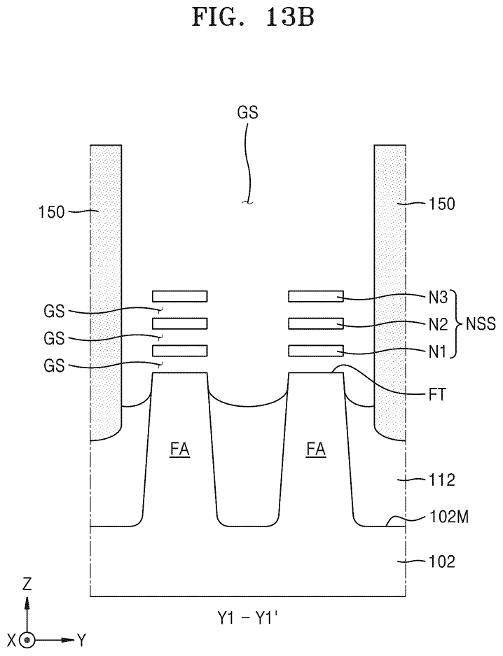

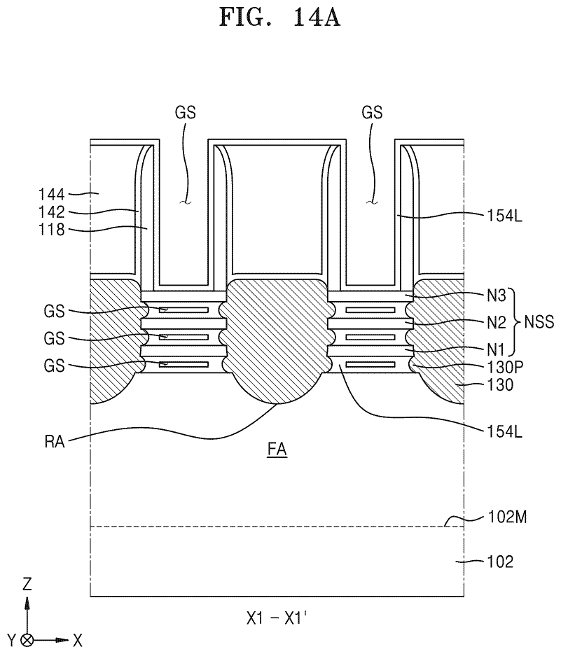

Referring to FIGS. 13A and 13B, a plurality of gate spaces GS may be prepared by removing the dummy gate structure DGS remaining in the resultant structure of FIG. 12, and the plurality of nanosheet stacks NSS may be exposed through the plurality of gate spaces GS. Afterwards, the plurality of sacrificial semiconductor layers 104 remaining on the resultant structure may be removed through the gate spaces GS, and thus, each of the gate spaces GS may extend to respective spaces between the first to third nanosheets N1, N2, and N3 and a space between the first nanosheet N1 and the fin top surface FT of the fin-type active region FA. As a result, an upper portion of the fin-type active region FA and a top surface of the device isolation film 112 may be exposed through the gate space GS.

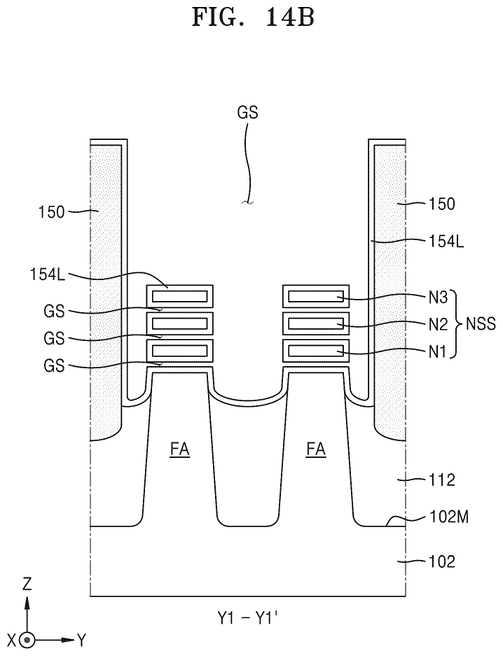

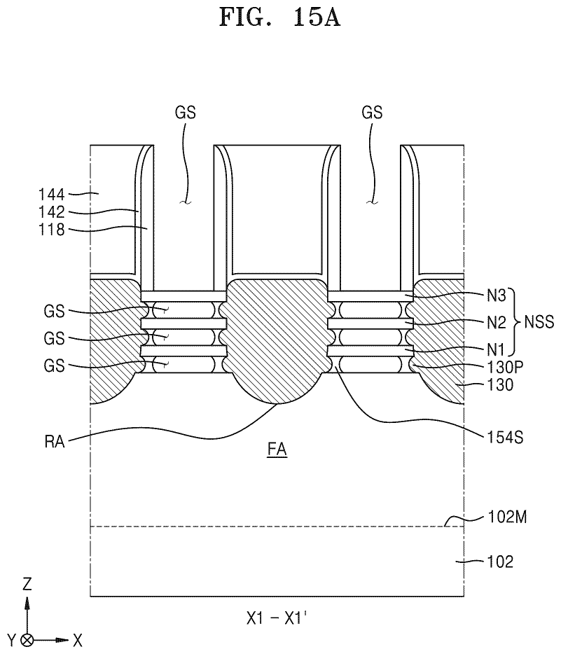

Referring to FIGS. 14A and 14B, an insulating film 154L may be formed to conformally cover an exposed surface of the resultant structure of FIGS. 13A and 13B. To form the insulating film 154L, after an atomic layer deposition (ALD) process of depositing an insulating material on an exposed surface of the resultant structure of FIGS. 13A and 13B is performed, the resultant structure including the deposited insulating material may be annealed. The insulating film 154L may include silicon nitride, silicon oxide, SiOC, SiOCN, SiCN, SiBN, SiON, SiBCN, SIOF, SiOCH, or a combination thereof.

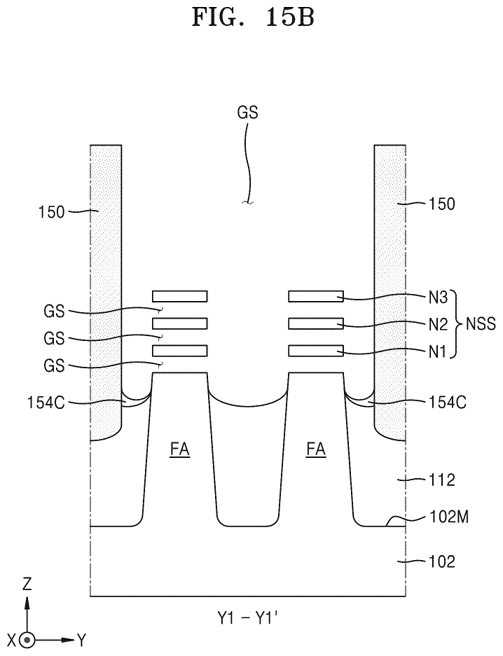

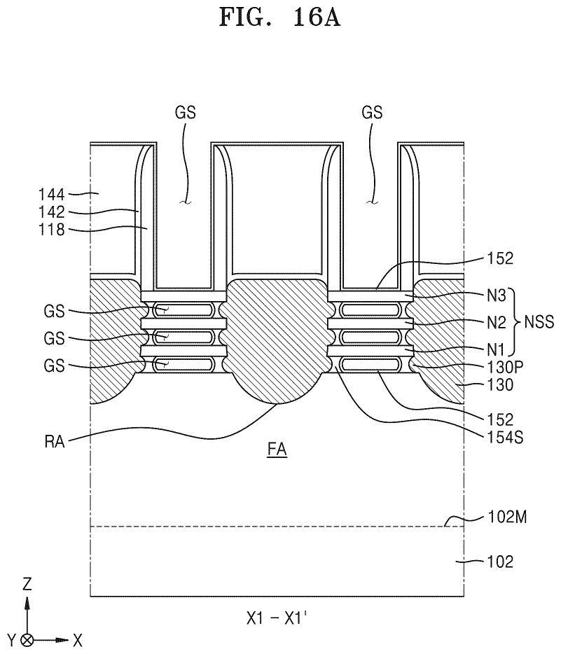

Referring to FIGS. 15A and 15B, a portion of the insulating film 154L may be removed by wet etching from the resultant structure of FIGS. 14A and 14B. A wet etching atmosphere and an etching time may be controlled such that the insulating film 154L remains in relatively narrow spaces in the resultant structure of FIGS. 14A and 14B. As a result, after the portion of the insulating film 154L is removed by using a wet etching process, a corner insulating spacer 154C, which is a part of the remaining portion of the insulating film 154L, may remain in a portion adjacent to a corner region defined by the device isolation film 112 and the gate cut insulating portion 150. Also, a plurality of inner insulating spacers 154S, which are other parts of the remaining portion of the insulating film 154L, may remain in relatively narrow spaces between the first to third nanosheets N1, N2, and N3 and between the fin top surface FT of the fin-type active region FA and the first nanosheet N1.

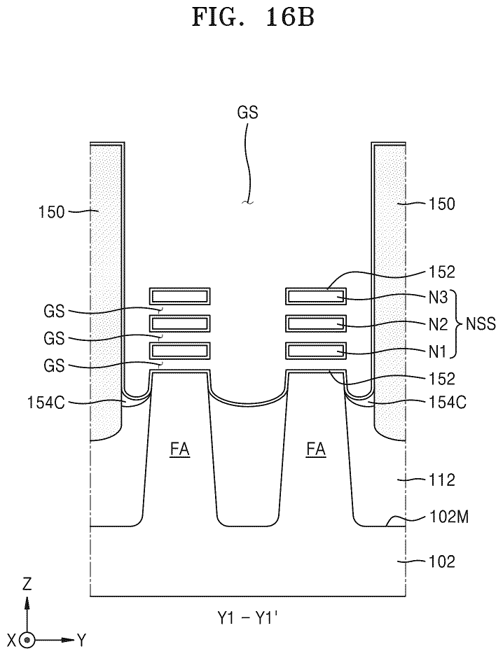

Referring to FIGS. 16A and 16B, a gate dielectric film 152 may be formed to conformally cover exposed surfaces in the resultant structure of FIGS. 15A and 15B.

The gate dielectric film 152 may include a portion covering exposed surfaces of each of the first to third nanosheets N1, N2, and N3, a portion covering respective exposed surfaces of the plurality of fin-type active regions FA, a portion covering respective exposed surfaces of the plurality of insulating spacers 118, a portion covering a surface of the corner insulating spacer 154C, a portion covering respective portions of the plurality of inner insulating spacers 154S, and portions covering surfaces of the device isolation film 112. The gate dielectric film 152 may be formed by using an ALD process.

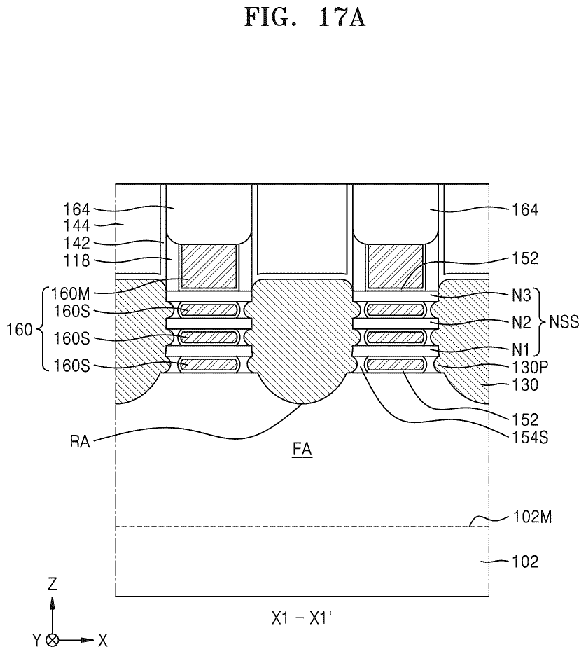

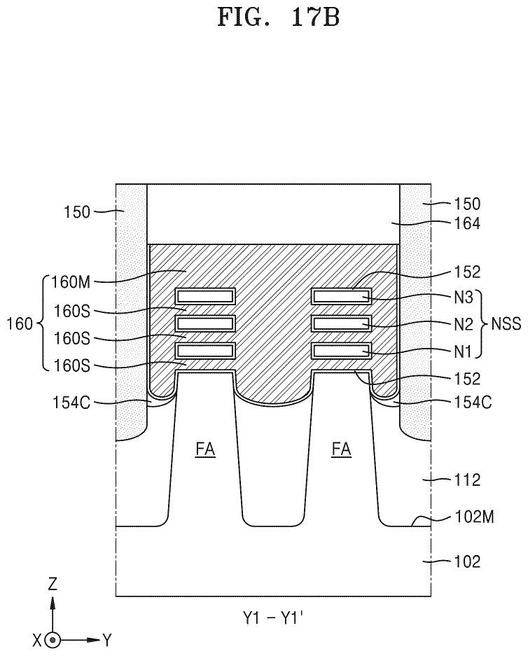

Referring to FIGS. 17A and 17B, a plurality of gate lines 160 filling the plurality of gate spaces (refer to GS in FIGS. 16A and 16B) may be formed on the gate dielectric film 152. An upper portion of each of the gate line 160, the gate dielectric film 152, and the outer insulating spacer 118 may be etched back to empty an upper partial space of each of the plurality of gate spaces GS again, and a capping insulating layer 164 may be formed in the upper partial space.

Thereafter, as shown in FIG. 2A, a portion of each of the inter-gate dielectric film 144 and the insulating liner 142 may be removed, and thus, a plurality of contact holes 170H exposing partial regions of the source/drain region 130 may be formed. Afterwards, a metal silicide film 172 may be formed on respective surfaces of the plurality of source/drain regions 130, which are exposed through the plurality of contact holes 170H, and a plurality of source/drain contacts 174 may be formed to fill the plurality of contact holes 170H, respectively. Thus, the IC device 100 shown in FIGS. 1 and 2A to 2C may be manufactured.

Although the method of manufacturing the IC device 100 shown in FIGS. 1 and 2A to 2C has been described with reference to FIGS. 8A to 17B, it will be understood that the IC devices 200, 300, 400, 500, and 600 shown in FIGS. 3 to 7 or IC devices having variously changed structures may be manufactured by applying various modifications and changes to the processes described with reference to FIGS. 8A to 17B within the scope of the inventive concepts.

For example, to manufacture the IC device 200 shown in FIG. 3, processes similar to those described with reference to FIGS. 8A to 17B may be performed. Here, to form a corner insulating spacer 254C having a multilayered structure including a first corner insulating film C1 and a second corner insulating film C2, a process similar to that described with reference to FIGS. 14A and 14B and a process similar to that described with reference to FIGS. 15A and 15B may be repeated a required number of times.

To manufacture the IC devices 300 and 400 shown in FIGS. 4 and 5, processes similar to those described with reference to FIGS. 8A to 17B may be performed. However, in the process described with reference to FIGS. 15A and 15B, an etching atmosphere and an etch rate of the insulating film 154L may be controlled, and thus, corner insulating spacers 354C and 454C having desired shapes may be formed.

To manufacture the IC device 500 shown in FIG. 6, processes similar to those described with reference to FIGS. 8A to 17B may be performed. However, in the process of forming the device isolation film 112, which has been described with reference to FIGS. 8A and 8B, the top surface of the device isolation film 112 may be formed to have a concave profile, and thus, end up relatively close to the substrate 102. In addition, by controlling the etching atmosphere and the etch rate of the insulating film 154L in the process described with reference to FIGS. 15A and 15B, the corner insulating spacer 154C and the middle insulating spacer 554M may be left from the insulating film 154L.

To manufacture the IC device 600 shown in FIG. 7, processes similar to those described with reference to FIGS. 8A to 17B may be performed. However, a process of forming an indent IND in each of the plurality of sacrificial semiconductor layers 104 may be omitted in the process described with reference to FIG. 10, and the process of FIG. 11 may be performed.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

While the inventive concepts have been particularly shown and described with reference to some example embodiments thereof, it will be understood that various changes in form and details may be made therein without departing from the spirit and scope of the following claims.

What is claimed is:

1. An integrated circuit device comprising:
a plurality of fin-type active regions extending in a first lateral direction on a substrate, the plurality of fin-type active regions being apart from each other in a second lateral direction, the second lateral direction intersecting with the first lateral direction;
a device isolation film covering sidewalls of each of the plurality of fin-type active regions;
a gate line extending in the second lateral direction on the plurality of fin-type active regions and the device isolation film;
a plurality of nanosheet stacks on a fin top surface of each of the plurality of fin-type active regions, each nanosheet stack comprising at least one nanosheet, and each nanosheet stack being surrounded by the gate line;
a gate cut insulating portion on the device isolation film, the gate cut insulating portion facing an end sidewall of the gate line in the second lateral direction; and
a corner insulating spacer between a first nanosheet stack and the gate cut insulating portion and between the device isolation film and the gate line, the first nanosheet stack being selected from the plurality of nanosheet stacks and being closest to the gate cut insulating portion in the second lateral direction.

2. The integrated circuit device of claim 1, wherein the corner insulating spacer is in contact with each of the gate cut insulating portion and the device isolation film.

3. The integrated circuit device of claim 1, wherein, in the second lateral direction, a first distance between the first nanosheet stack and the gate cut insulating portion is less than a distance between two adjacent ones of the plurality of nanosheet stacks.

4. The integrated circuit device of claim 1, wherein a first vertical level of an uppermost portion of the corner insulating spacer, which is farthest from the substrate, is closer to the substrate than a second vertical level of the fin top surface of each of the plurality of fin-type active regions.

5. The integrated circuit device of claim 1, further comprising a gate dielectric film surrounding the gate line,
wherein the gate dielectric film is between the gate line and the corner insulating spacer and between the gate line and the gate cut insulating portion.

6. The integrated circuit device of claim 1, wherein the corner insulating spacer has a multilayered structure including a plurality of corner insulating films sequentially stacked one-by-one on the device isolation film.

7. The integrated circuit device of claim 1, further comprising a pair of inner insulating spacers in a first space between one fin-type active region selected from the plurality of fin-type active regions and the at least one nanosheet,
wherein the pair of inner insulating spacers cover both sidewalls of a sub-gate portion filling the first space of the gate line, and
wherein at least some of the pair of inner insulating spacers comprise a same material as a constituent material of the corner insulating spacer.

8. The integrated circuit device of claim 7, further comprising a source/drain region in contact with a selected one of the pair of inner insulating spacers, wherein the source/drain region comprises a protrusion that is convex toward the sub-gate portion.

9. The integrated circuit device of claim 7, further comprising a source/drain region in contact with a selected one of the pair of inner insulating spacers,
wherein the selected inner insulating spacer comprises a first sidewall facing the gate line and a second sidewall facing the source/drain region, and
wherein the first sidewall and the second sidewall are asymmetrical with each other.

10. The integrated circuit device of claim 1, wherein a top surface of the corner insulating spacer, which faces the gate line, has a concave shape toward the gate line.

11. The integrated circuit device of claim 1, wherein a top surface of the corner insulating spacer, which faces the gate line, comprises an inclined surface that extends away from the substrate toward the gate cut insulating portion.

12. The integrated circuit device of claim 1, wherein a top surface of the corner insulating spacer, which faces the gate line, comprises a planar surface that extends in the second lateral direction.

13. The integrated circuit device of claim 1, further comprising a middle insulating spacer between the first nanosheet stack and a second nanosheet stack and between device isolation film and the gate line, the second nanosheet stack being adjacent to the first nanosheet stack in the second lateral direction, from among the plurality of nanosheet stacks,
wherein a thickness of the middle insulating spacer is less than a thickness of the corner insulating spacer in a vertical direction.

14. An integrated circuit device comprising:
a fin-type active region extending in a first lateral direction on a substrate;
a device isolation film covering sidewalls of the fin-type active region;
a plurality of nanosheets on a fin top surface of the fin-type active region, the plurality of nanosheets overlapping each other in a vertical direction;
a gate line extending long in a second lateral direction on the fin-type active region and the device isolation film, the gate line surrounding the plurality of nanosheets, the second lateral direction intersecting with the first lateral direction;
a source/drain region on the fin-type active region, the source/drain region being in contact with the plurality of nanosheets;
a gate cut insulating portion on the device isolation film, the gate cut insulating portion facing an end sidewall of the gate line in the second lateral direction;
a corner insulating spacer between the plurality of nanosheets and the gate cut insulating portion and between the device isolation film and the gate line; and
a plurality of inner insulating spacers respectively one-by-one between the plurality of nanosheets, each inner insulating spacer being between the source/drain region and the gate line in the first lateral direction,
at least some of the plurality of inner insulating spacers comprising a same material as a constituent material of the corner insulating spacer.

15. The integrated circuit device of claim 14, wherein a first vertical level of an uppermost portion of the corner insulating spacer, which is farthest from the substrate, is closer to the substrate than a second vertical level of the fin top surface of the fin-type active region.

16. The integrated circuit device of claim 14, wherein the corner insulating spacer comprises a portion of which a thickness in the vertical direction increases toward the gate cut insulating portion in the second lateral direction.

17. The integrated circuit device of claim 14, wherein the corner insulating spacer has a multilayered structure comprising a plurality of corner insulating films sequentially stacked one-by-one on the device isolation film.

18. The integrated circuit device of claim 14, further comprising a source/drain contact adjacent to each of the gate cut insulating portion and the gate line, the source/drain contact being connected to the source/drain region,
wherein the corner insulating spacer and the source/drain contact overlap each other in the first lateral direction.

19. The integrated circuit device of claim 14, wherein each of the plurality of inner insulating spacers comprises a first sidewall facing the gate line and a second sidewall facing the source/drain region, and
the first sidewall is asymmetrical with the second sidewall.

20. An integrated circuit device comprising:
a plurality of fin-type active regions extending in a first lateral direction on a substrate;
a device isolation film covering sidewalls of each of the plurality of fin-type active regions;
a plurality of nanosheet stacks on a fin top surface of each of the plurality of fin-type active regions, each nanosheet stack comprising a plurality of nanosheets;
a gate line extending long in a second lateral direction on the plurality of fin-type active regions and the device isolation film, the gate line surrounding a first nanosheet stack, which is selected from the plurality of nanosheet stacks, the second lateral direction intersecting with the first lateral direction;
a source/drain region on the plurality of fin-type active regions, the source/drain region being in contact with the first nanosheet stack;
a gate cut insulating portion adjacent to the first nanosheet stack on the device isolation film, the gate cut insulating portion facing an end sidewall of the gate line in the second lateral direction;
a corner insulating spacer between the first nanosheet stack and the gate cut insulating portion and between the device isolation film and the gate line; and
a plurality of inner insulating spacers respectively one-by-one between the plurality of nanosheets included in the first nanosheet stack, each inner insulating spacer being in contact with the source/drain region,
wherein each of the corner insulating spacer and the plurality of inner insulating spacers comprises silicon nitride, silicon oxide, silicon oxycarbide (SiOC), silicon oxycarbonitride (SiOCN), silicon carbonitride (SiCN), silicon boron nitride (SiBN), silicon oxynitride (SiON), silicon boron carbonitride (SiBCN), fluorinated silicon oxide (SiOF), hydrogenated silicon oxycarbide (SiOCH), or a combination thereof, and
at least some of the plurality of inner insulating spacers comprise a same material as a constituent material of the corner insulating spacer.
